(19) United States
(12) Patent Application Publication
(10) Pub. No.: US 2024/0237242 A1
(43) Pub. Date: Jul. 11, 2024

(54) STRUCTURAL SUPPORT FOR A DISPLAY APPARATUS

(71) Applicant: Rosen Aviation, LLC, Eugene, OR (US)

(72) Inventors: Brock E. Ferguson, Cottage Grove, OR (US); Scott A. Charles, Eugene, OR (US)

(73) Assignee: Rosen Aviation, LLC, Eugene, OR (US)

(21) Appl. No.: 18/521,892

(22) Filed: Nov. 28, 2023

Related U.S. Application Data
(60) Provisional application No. 63/437,284, filed on Jan. 5, 2023.

(51) Int. Cl. H05K 5/02; B32B 7/12; B32B 37/12

(52) U.S. Cl. CPC H05K 5/0217; B32B 7/12; B32B 37/12; B32B 2457/20

(57) ABSTRACT

A method for improving structural support for a display apparatus comprising a flat panel display and a circuit board situated at a back side of the flat panel display can include preparing a chassis, applying a first adhesive member to selective areas on a front surface of the chassis, and bonding the front surface of the chassis to the back side of the flat panel display using the first adhesive member. The first adhesive member is deformable under a shear force that is coplanar with the flat panel display.

### CROSS-REFERENCE TO RELATED APPLICATION

This application claims the benefit of U.S. Provisional Application No. 63/437,284, filed Jan. 5, 2023, which is incorporated by reference herein.

### FIELD

The present disclosure generally concerns systems and methods for providing structural support for flat panel display apparatuses, specifically for organic light-emitting diode (OLED) displays and/or liquid-crystal displays (LCDs) used in aviation industry.

### BACKGROUND

The flat panel displays are used in a wide range of applications, including televisions, computer monitors, instrument panels, aircraft cockpit displays, etc. Modern flat panel displays, such as organic LED (OLED) displays, micro-LED displays, etc., are becoming thinner and more lightweight. However, they may also be more prone to damage under load and/or changing environmental conditions. This problem can be particularly challenging in the aviation industry. For example, any flat panel displays mounted on an aircraft are required to pass rigorous abuse load test, and they must also remain safely mounted under various environmental conditions (e.g., changing in cabin temperature, humidity, etc.). Thus, room for improvements exists for proper improving structural support for the thin flat panel displays.

### SUMMARY

The present disclosure relates to systems and methods for providing structural support for flat panel display apparatuses, such as thin flat panel display apparatuses, e.g., LCD, OLED, miniLED, and micro-LED flat panel displays.

Certain examples of the disclosure concern a method for improving structural support for a display apparatus comprising a flat panel display and a first chassis mounted on a back side of the flat panel display.

According to certain examples, the method can include identifying internal voids of the display apparatus located between the flat panel display and the first chassis, and filling selected internal voids with a curable liquid filler.

According to certain examples, the method can include affixing a second chassis to the first chassis, identifying electronic components of the flat panel display that are not covered by the first chassis, and creating a direct load path between the flat panel display and the second chassis. The direct load path is configured to shield the electronic components from contacting the second chassis. A front surface of the second chassis is configured to mate with a back surface of the first chassis.

Certain examples of the disclosure concern an assembly for improving structural support for a display apparatus which includes a flat panel display and a first chassis mounted on a back side of the flat panel display. The assembly can include a second chassis affixed to the first chassis, and one or more braces connecting the back side of the flat panel display to a front surface of the second chassis. The front surface of the second chassis is configured to mate with a back surface of the first chassis. The one or more braces include respective recesses configured to accommodate electronic components of the flat panel display that are not covered by the first chassis.

Certain examples of the disclosure also concern a method for improving structural support for a display apparatus including a flat panel display and a circuit board situated at a back side of the flat panel display.

The method can include preparing a chassis, applying a first adhesive member to selective areas on a front surface of the chassis, and bonding the front surface of the chassis to the back side of the flat panel display using the first adhesive member. The first adhesive member is deformable under a shear force that is coplanar with the flat panel display.

Certain examples of the disclosure also concern an assembly for improving structural support for a display apparatus including a flat panel display and a circuit board situated at a back side of the flat panel display. The assembly can include a chassis having a front surface configured to mate with the back side of the flat panel display, and a first adhesive member attached to selective areas of the front surface of the chassis. The first adhesive member is configured to bond the front surface of the chassis to the back side of the flat panel display. The first adhesive member is deformable under a shear force that is coplanar with the flat panel display.

The foregoing and other objects, features, and advantages of the invention will become more apparent from the following detailed description, which proceeds with reference to the accompanying figures.

### BRIEF DESCRIPTION OF THE DRAWINGS

FIG. 1 depicts an example flat panel display and areas used for abuse load test.

FIG. 2A depicts a front view of a display assembly, according to one example.

FIG. 2B depicts a rear view of the display assembly of FIG. 2A.

FIG. 3 is an exploded view of the display assembly of FIG. 2A, the display assembly comprising a flat panel display having a built-in factory chassis, a custom chassis, and other components.

FIG. 4 is rear perspective view of the flat panel display of FIG. 3, according to one example.

FIG. 5A depicts a circuit board and associated flat flex cables embedded in the flat panel display of FIG. 4, according to another example.

FIG. 5B depicts placement of braces over the flat flex cables of FIG. 5A, according to one example.

FIG. 5C depicts a bottom view of a brace of FIG. 5B, according to one example.

FIG. 5D depicts a side view of the brace of FIG. 5C, according to one example.

FIG. 6 depicts placement of the braces between the flat panel display and the customer chassis of FIG. 3, according to one example.

FIG. 7 depicts another example display assembly comprising a flat panel display (without a built-in factory chassis) and a custom chassis.

FIG. 8 depicts a front surface of the custom chassis of FIG. 7, according to one example.

FIG. 9 illustrates application of adhesive tapes and spacers to the front surface of the custom chassis of FIG. 8, according to one example.

FIG. 10A illustrates application of sealants to a recessed portion of the custom chassis of FIG. 8, according to one example.

FIG. 10B is a side cross-sectional view of a portion of the custom chassis of

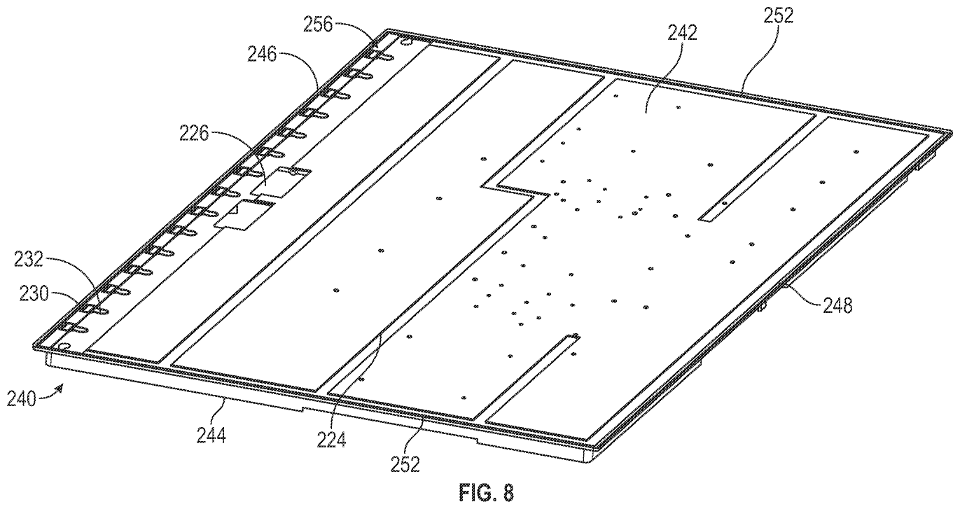

FIG. 8, according to one example.

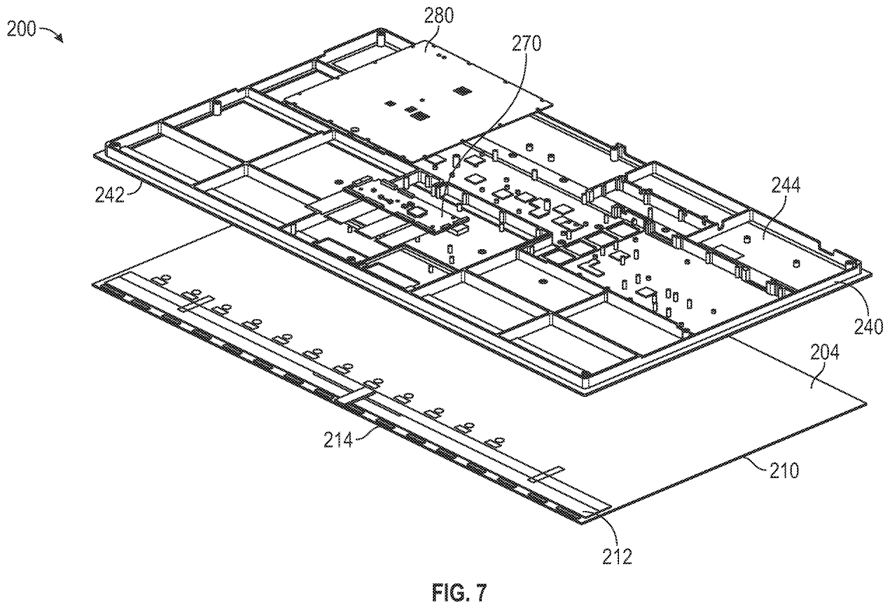

FIG. 11 illustrates a process for assembling the display assembly of FIG. 7, according to one example.

### DETAILED DESCRIPTION

### General Considerations

For purposes of this description, certain aspects, advantages, and novel features of the examples of this disclosure are described herein. The disclosed methods, apparatus, and systems should not be construed as being limiting in any way. Instead, the present disclosure is directed toward all novel and nonobvious features and aspects of the various disclosed examples, alone and in various combinations and sub-combinations with one another. The methods, apparatus, and systems are not limited to any specific aspect or feature or combination thereof, nor do the disclosed embodiments require that any one or more specific advantages be present or problems be solved. The technologies from any example can be combined with the technologies described in any one or more of the other examples. In view of the many possible embodiments to which the principles of the disclosed technology may be applied, it should be recognized that the illustrated embodiments are only representative examples and should not be taken as limiting the scope of the disclosed technology.

Although the operations of some of the disclosed examples are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed methods can be used in conjunction with other methods. Additionally, the description sometimes uses terms like “provide” or “achieve” to describe the disclosed methods. These terms are high-level abstractions of the actual operations that are performed. The actual operations that correspond to these terms may vary depending on the particular implementation and are readily discernible by one of ordinary skill in the art.

As used in this application and in the claims, the singular forms “a,” “an,” and “the” include the plural forms unless the context clearly dictates otherwise. Additionally, the term “includes” means “comprises.” Further, the terms “coupled” and “connected” generally mean electrically, electromagnetically, and/or physically (e.g., mechanically or chemically) coupled or linked and does not exclude the presence of intermediate elements between the coupled or associated items absent specific contrary language.

Directions and other relative references (e.g., inner, outer, upper, lower, etc.) may be used to facilitate discussion of the drawings and principles herein, but are not intended to be limiting. For example, certain terms may be used such as “inside,” “outside,”, “top,” “bottom,” “interior,” “exterior,” and the like. Such terms are used, where applicable, to provide some clarity of description when dealing with relative relationships, particularly with respect to the illustrated embodiments. Such terms are not, however, intended to imply absolute relationships, positions, and/or orientations.

For example, with respect to an object, an “upper” part can become a “lower” part simply by turning the object over. Nevertheless, it is still the same part and the object remains the same. As used herein, “and/or” means “and” or “or”, as well as “and” and “or”.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims.

### Overview of Display Apparatuses Used in Aviation Industry

Flat panel displays (e.g., LCDs) have been widely used in the aviation industry. They have replaced the conventional CRT display units used in the commercial aircraft due to their superiority in terms of space, viewability (both in sunlight and at night), weight, reliability, power consumption, and others. Besides being commonly used in the seating area serving in-flight entertainment purposes, flat panel displays are also vitally important in aircraft cockpits for navigational purposes. In general, flat panel displays mounted on the aircraft can provide mapping and weather information, information concerning terrain elevation, altitude, alerts, and provide other necessary or helpful information for flight in a commercial aircraft.

On the other hand, aircraft-mounted flat panel displays must also adhere to a number of standards and expectations for safety purposes. For example, they need to be visible in all lighting conditions, resistant to damage, and offer ease of use. Flat panel displays for aircraft are also subjected to more severe environments as to temperature, barometric pressure, vibration, impact, etc. than flat panel displays for ordinary use.

Earlier generations of flat panel displays are relatively more immune to loading conditions because they have more inherent structural support and contain more and thicker layers. But cracking of flat panel displays has become a major problem with the introduction of thinner and more fragile display technologies such as OLEDs and micro-LED displays. These new flat panel displays lack the inherent support provided by the diffuser and light guide that are integral part of conventional flat panel displays.

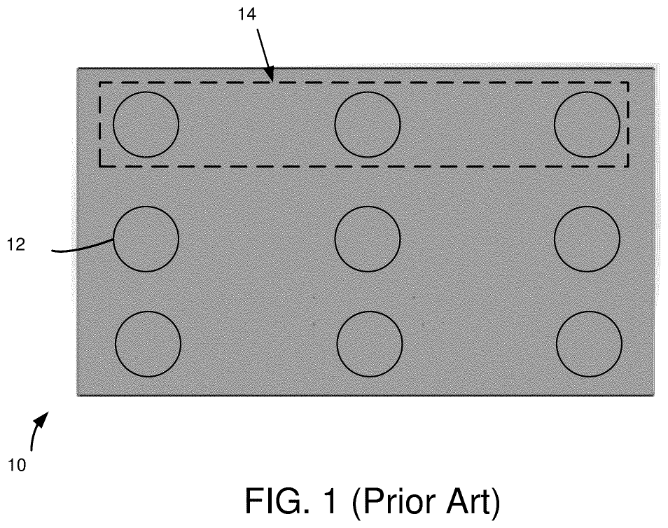

Off-the-shelf flat panel displays are usually not feasible to be directly mounted on aircraft. One reason is that federal aviation regulations require all flight-mounted flat panel displays pass both static and dynamic abuse loading tests. As an example, FIG. 1 shows a standard flat panel display 10, which is subject to an abuse loading test. An example abuse loading test applies 300 lb. force over multiple circular areas 12 having about a 6-inch diameter on the front surface of the flat panel display 10. If the flat panel display 10 is not properly supported on the back side, such abuse loading condition can damage the display panel.

Some flat panel displays have a built-in chassis which does not uniformly support the back side of the display panels. Such non-uniform back support can be due to irregular geometry of the built-in chassis and/or hinderance of electronics associated with the flat panel displays. For example, the flat panel display 10 of FIG. 1 can have a built-in chassis at the back side which provides structural support for middle and lower portions of the display panel, but leaves an upper portion 14 of the display panel unsupported due to the placement of circuit board(s) and/or some flexible cables in the upper portion 14. As a result, when loads are applied to those circular areas 12 that are located within the unsupported upper portion 14, cracking of the flat panel display 10 may occur. This can cause internal damage to the flat panel display 10 and render it non-functional, and may even provide a safety risk to the passengers and/or flight personnel nearby.

Some flat panel displays have no built-in chassis. For example, some flat panel displays only include flat panel screens and associated circuit boards and cables. In such circumstances, custom chassis can be designed and bonded to the back side of the flat panel displays. For aircraft application, it is desirable to use lightweight materials for the chassis to reduce fuel consumption and increase cargo capacity for use elsewhere. These lightweight materials often have a different coefficient of thermal expansion (CTE) than the materials of the flat panel display to which the chassis is bonded. As the temperature changes in the airplane cabin, shear stresses can be created between different materials used in the chassis and the flat panel display, which can lead to bond failures and/or delamination between the chassis and the flat panel display, causing damage to the display panel and/or presenting a safety risk.

The technologies described herein can overcome many of the challenges described above. Specifically, improved structural support can be provided for flat panel displays. Such improved structural support can be applied to all display-based products, particularly those that are thin and fragile such as OLEDs, miniLED, and micro-LED panels. Further, it is to be understood that the disclosed technologies are not limited to the aviation industry. Instead, the disclosed technologies can be applied to the general transportation industry (e.g., for mounting thin panel displays in cars, buses, trains, boats, etc.), home and office industries, manufacturing factories, and other industries.

### Improving Structural Support for Flat Panel Displays Having Built-in Chassis

As described above, some flat panel displays have built-in chassis provided by the flat panel manufacturers. Flat panels that come with built-in factory chassis are often inadequate in design for the aviation industry and cannot pass the required abuse loading test. In some circumstances, the built-in factory chassis does not provide uniform structural support for the back side of the flat panel displays. In some circumstances, flat panel displays with factory chassis have internal voids which create vulnerable spots on the flat panel screen which are prone to crack during abuse loading tests.

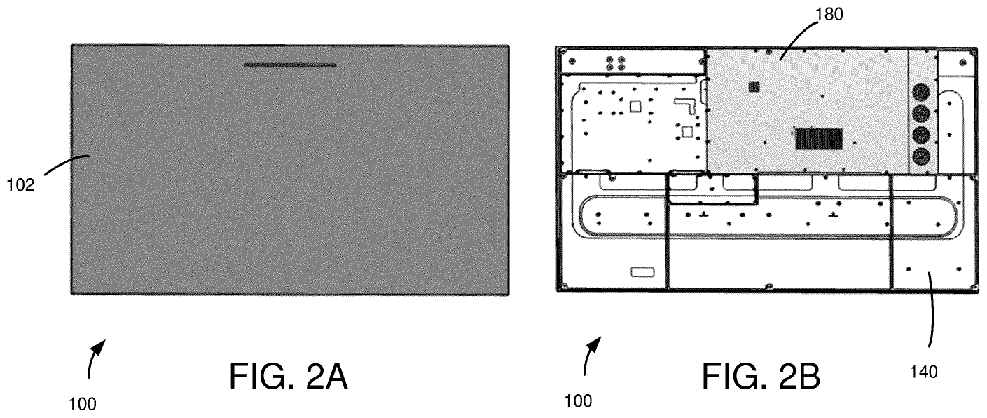

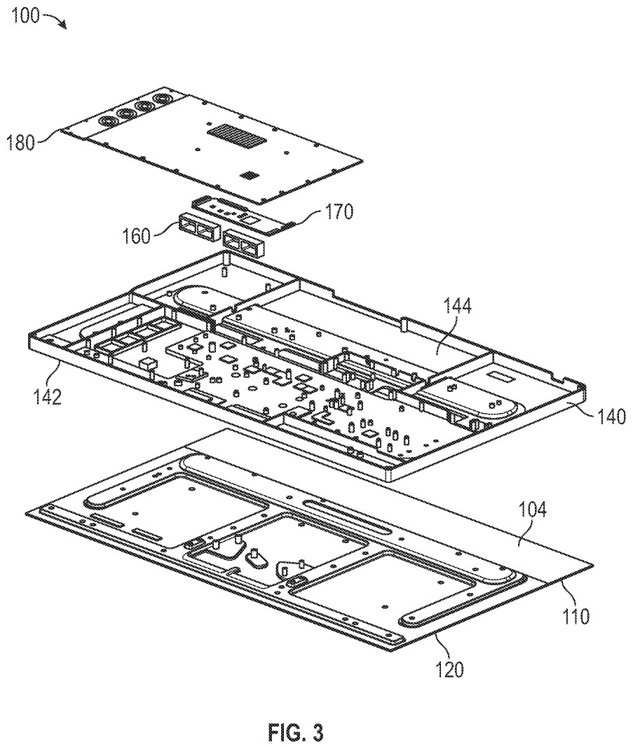

According to certain aspects of the disclosure, a custom chassis can be added to the back of a flat panel display having a built-in factory chassis to provide additional structural support for the flat panel display so that it can pass the abuse loading tests. As one example, FIGS. 2A-2B and FIG. 3 show a display assembly 100 which includes a flat panel display 110, a built-in factory chassis 120, and a custom chassis 140.

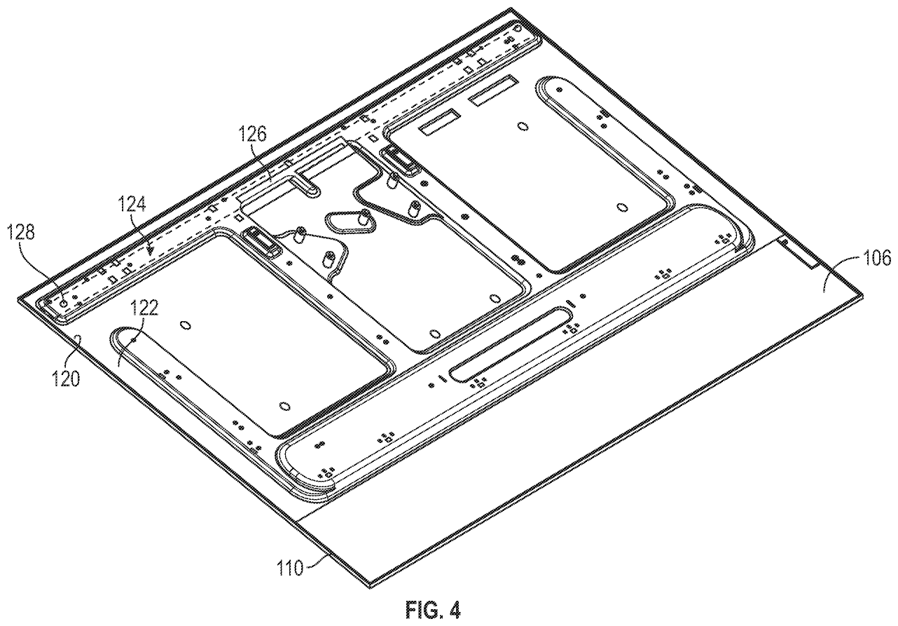

The front surface of the flat panel display 110 is a planar or substantially planar screen 102 to which the abuse loading tests can be applied. As shown in FIG. 4, the factory chassis 120 is bonded to a back side 104 of the flat panel display 110. In some circumstances, the bond between the flat panel display 110 and the factory chassis is sufficiently strong such that the factory chassis 120 cannot be removed from the flat panel display 110 without damaging the flat panel display 110. In some circumstances, the factory chassis 120 may not cover the entire back side 104 of the flat panel display 110. For example, FIG. 4 shows that a lower portion 106 of the back side 104 is not covered by the factory chassis 120. As described herein, the custom chassis 140 is configured to be removably coupled to the back side 104 of the flat panel display 110 and the custom chassis 140, as described further below.

In certain examples, the display assembly 100 includes additional components. For example, FIG. 3 shows that the display assembly 100 can include a timing controller (“TCON”) 170 which is a circuit board configured to receive image data and process the image data to drive the individual pixel components of the images displayed on the screen of the flat panel display 110. In some circumstances, the TCON 170 can be deemed part of the flat panel display 110. In some examples, the TCON 170 can be secured to a back side 144 of the custom chassis 140. In some examples, the display assembly 100 can also include one or more (two are shown in FIG. 3) braces 160 (also referred to as spacers) which can be placed between the flat panel display 110 and the custom chassis 140, as described more fully below. In some examples, the display assembly 100 can further include a back cover 180 configured to cover at least a portion of the back side 144 of the custom chassis 140 (e.g., covering the TCON 170). The back cover can serve as an eletronic cover (e.g., covering the TCON 170), an electromatic interference shield, a thermal dissipation device, and/or a structural member.

The custom chassis 140 can be made of a lightweight material such as high-strength steel, magnesium alloys, aluminum alloys, carbon fiber, and polymer and/or plastic composites. In particular embodiments, it is made of aluminum.

As described herein, the custom chassis 140 is configured to provide a uniform support for the entire back of the flat panel display 110 including the factory chassis 120. Specifically, the custom chassis 140 can be customarily fabricated so that a front surface 142 (which may also be referred to as an inner surface) of the custom chassis 140 is configured to mate with a back surface 122 of the factory chassis 120. Additionally, the front surface 142 of the custom chassis 140 is configured to mate with any portions of the back side 104 of the flat panel display 110 that are not covered by the factory chassis 120, e.g., the lower portion 106 depicted in FIG. 4. In other words, the front surface 142 of the custom chassis 140 is configured to contact the entire back surface 122 of the factory chassis 120 and portions of the back side 104 of the flat panel display 110 that are not covered by the factory chassis 120.

The custom chassis 140 can be affixed to the factory chassis 120 via a number of means. In one example, the customer chassis 140 can be fixedly attached to the factory chassis 120 by one or more fasteners (e.g., screws, brackets, etc.). In another example, the custom chassis 140 can be coupled to the factory chassis 120 by means of press fit. In yet a further example, the custom chassis 140 can be bonded to the factory chassis 120 (e.g., using adhesives, etc.).

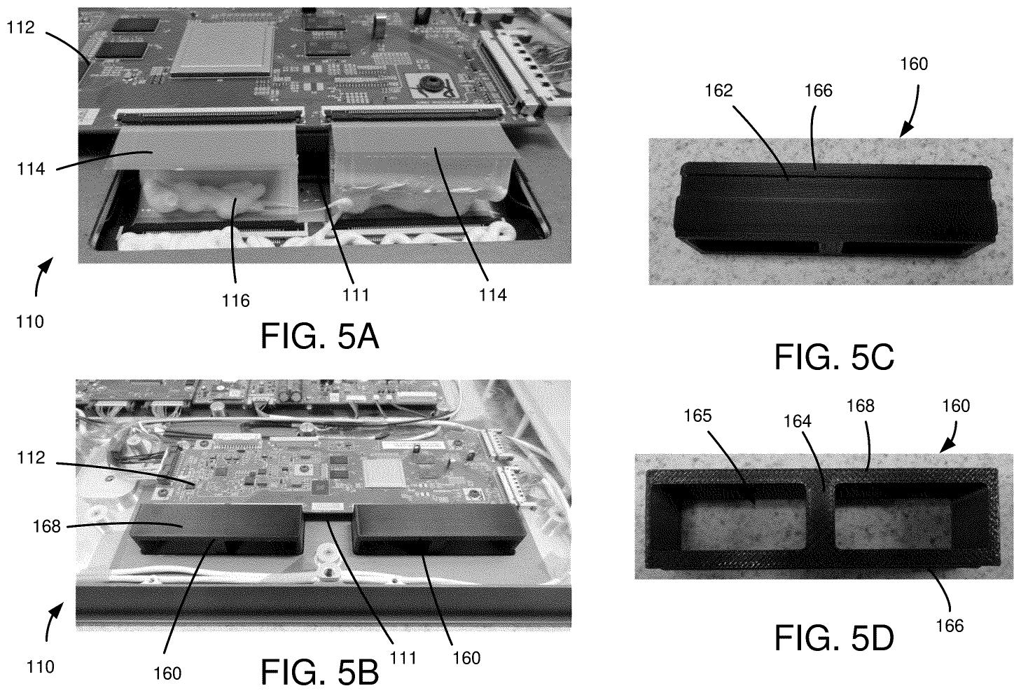

In some circumstances, the factory chassis 120 does not provide direct support for certain covered areas of the back side 104 of the flat panel display 110. For example, the flat panel display 110 can have a flat screen 111 and one or more circuit board(s) 112 (FIGS. 5A-5B) attached to the flat screen 111 (e.g., situated at the back side 104). The circuit board(s) 112 can be covered by the factory chassis 120. The circuit board(s) 112 can have an uneven surfaces due to the presence of some electronic components. As a result, empty spaces or internal voids 124 (marked by the dashed box in FIG. 4) may form between the flat screen 111 and the circuit board(s) 112 and/or between the circuit board(s) 112 and the factory chassis 120. Such internal voids 124 can create vulnerable spots for the planar screen 102 because an abuse load applied to the planar screen 102 overlying the internal voids 124 can cause the flat panel display 110 to deform into the internal voids and result in cracks.

According to certain aspects of the disclosure, such internal voids 124 can be identified before attaching the custom chassis 140 to the factory chassis 120 and the flat panel display 110. In some examples, the locations and sizes of the internal voids 124 (i.e., empty spaces) can be found via visual inspection and/or based on evaluation of CAD models (e.g., the 3D images files) for the flat panel display 110 and the factory chassis 120. In some examples, the locations and sizes of the internal voids 124 can be found experimentally, for example, though small deflection test of suspected areas.

In some examples, a curable liquid or paste filler such as an epoxy (e.g., DP-110 supplied by 3M Company, etc.) can be injected into the identified internal voids 124. The angle and amount of the injection can be adjusted to ensure that the liquid or paste filler completely fills those identified internal voids. Once cured, the liquid or paste filler filling the internal voids 124 can prevent local deformation (and subsequent cracking) of the flat panel display caused by the abuse load, thereby improving the tolerance of the flat panel display 110 against the applied abuse load. As described herein, the liquid or paste filler is selected to avoid puddling once cured. In certain examples, the liquid or paste filler can include a low shrinkage material that meets flammability requirements, as well as a working temperature range (e.g., −55° C. to +85° C.).

In some circumstances, the factory chassis 120 can have one or more apertures 128 which provide access to the internal voids 124. In such cases, the liquid or paste filler can be injected through those apertures 128. In some instances when there is no direct access to the internal void(s), opening(s) connected to the internal voids 124 can be created on the factory chassis 120 (e.g., by drilling, etc.) so that the liquid or paste filler can be injected therethrough.

In some circumstances, the factory chassis 120 can have one or more openings 126 which allow some electronic components (e.g., wires, harnesses, cables, etc.) of the flat panel display 110 to pass through. For example, FIG. 5A shows that the circuit board(s) 112 of the flat panel display 110 can be connected to one or more flat flex cables 114, which can extend through openings 126 of the factory chassis 120 for connecting to other components (e.g., the TCON 170, etc.).

In some circumstances, it may not be feasible to directly support, either using the factory chassis 120 or the custom chassis 140, areas of the back side 104 (of the flat panel display 110) where the flat flex cables 114 are located. In such cases, a direct load path can be created between the flat panel display 110 and the custom chassis 140. The direct load path can be configured to shield the flat flex cables 114 (or any other electronic components extending through the openings 126) from contacting the custom chassis 140.

In some examples, as depicted in FIG. 5B, the direct load path can be created by covering the flat flex cables 114 (or any other electronic components extending through the openings 126) with one or more braces 160. The braces 160 can be made of any lightweight load bearing materials, such as polymer and/or plastic composites, stainless steel, carbon fiber, magnesium and/or aluminum alloys, etc.

As shown in FIGS. 5C-5D, each brace 160 can have a top surface 168 and a bottom surface 166 connected by one or more walls 164. The height of the braces 160 is configured to be approximately the same as the distance from the back side 104 of the flat panel display 110 to the front surface 142 of the custom chassis 140 (at the location of the flat flex cables 114) when the custom chassis 140 is coupled to the factory chassis 120 and the flat panel display 110. The shape of the top surface 168 can be configured to match the corresponding shape of the front surface 142 of the custom chassis 140 (at the location of the flat flex cables 114). Thus, when mounted, the top surface 168 of each brace 160 can seamlessly contact the front surface 142 of the custom chassis 140, and the bottom surface 166 of each brace 160 interfaces with the back side 104 of the flat panel display 110 around the flat flex cables 114. As a result, any load pressure applied to the flat panel display 110 at the location of the flat flex cables 114 can be transmitted to the custom chassis 140 through the braces 160.

In some examples, as depicted in FIG. 5C, the bottom surface 166 of each brace 160 can have a recess 162 configured to accommodate the corresponding electronic components such as the flat flex cables 114. In some examples, each brace 160 can have cavities 165 located between the walls 164 so as to reduce the material usage and overall weight of the brace 160.

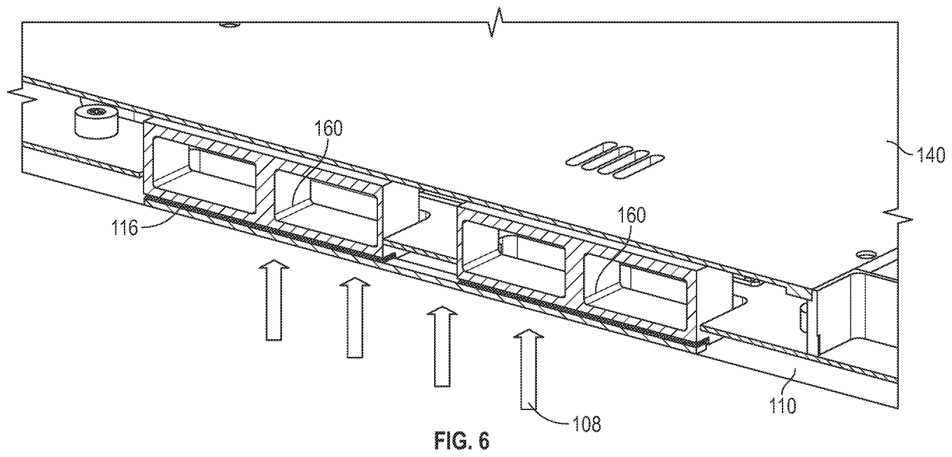

In certain examples, before placing the braces 160 over the flat flex cables 114, another liquid or paste filler, such as a room-temperature-vulcanizing (RTV) silicone 116 can be applied to the recesses 162 and/or the flat flex cables 114 (FIG. 5A). Other example paste fillers include, but are not limited to: butyl rubber, latex caulk, polyurethane, and epoxies. In one example, the RTV silicone 116 can fill the recesses 162. Thus, as illustrated in FIG. 6, when a load (as indicated by the block arrows 108) is applied to the front surface of the flat panel display 110 at an area overlying the braces 160, the RTV silicone 116 can be squeezed (under the load pressure) to conform to the contours of the bottom surface 166 of each brace 160, its interfacing back side 104 of the flat panel display 110, and the flat flex cables 114 sandwiched therebetween. Thus, the RTV silicone 116 can serve as a gap filler between the braces 160 and their interfacing back side 104 of the flat panel display 110. As a result, areas of the back side 104 (of the flat panel display 110) where the flat flex cables 114 are located can be indirectly supported by the custom chassis 140 through the direct load path created by the braces 160.

### Improving Structural Support for Flat Panel Displays Without Built-in Chassis

As described above, some flat panel displays have no built-in chassis, and they need to be supported by custom chassis in order to mount such flat panel displays on an aircraft or other places. Although the custom chassis can be bonded to the back side of such flat panel displays, bonding failure may occur if the materials used in the custom chassis have a different CTE than the materials of the flat panel display. For example, temperature change can create a shear stress between different materials which can cause delamination between the custom chassis and the flat panel display.

According to certain aspects of the disclosure, a custom chassis can be directly affixed to the back side of a flat panel display (without a built-in factory chassis) using a flexible substrate. The flexible substrate can act like a spring to reduce shear stresses caused by the CTE differences between different materials of the custom chassis and the flat panel display across a prespecified temperature range (e.g., between −55° C. and 85° C., inclusive).

As one example, FIG. 7 show a display assembly 200 which includes a flat panel display 210 and a custom chassis 240. The flat panel display 210 can be similar to the flat panel display 110 described above, except for having no built-in factory chassis (e.g., 120). In some examples, the display assembly 200 also includes additional components, such as a TCON 270 (similar to TCON 170) and a back cover 280 (similar to 180). In some examples, the TCON 270 can be deemed part of the flat panel display 210. In some examples, the TCON 270 can be secured to a back side 244 of the custom chassis 240. In some examples, the back cover 280 is configured to cover at least a portion of the back side 244 of the custom chassis 240 (e.g., covering the TCON 270).

The flat panel display 210 can have one or more circuit boards 212 situated at a back side 204 of the flat panel display 210. In the depicted example, the circuit board(s) 212 are located at an upper portion (near a top edge) of the back side 204 of the flat panel display 210. In some examples, the circuit board(s) 212 can be electrically connected to the back side 204 of the flat panel display 210 via a plurality of flat flex cables (FFCs) 214. The circuit board(s) 212 can be bonded to the back side 204 of the flat panel display either from the factory or later.

Likewise, the custom chassis 240 can be made of a lightweight material such as high-strength steel, magnesium alloys, aluminum alloys, carbon fiber, and polymer and/or plastic composites.

The custom chassis 240 is configured to provide a uniform support for the entire back or substantially the entire back of the flat panel display 210. The back side 204 of the flat panel display 210 is substantially flat except for the upper portion where the circuit board(s) 212 have a raised profile. The custom chassis 240 can be customarily fabricated so that a front surface 242 (which may also be referred to as an inner surface) of the custom chassis 240 is flat or substantially flat except in its upper part which has a recessed portion 256 configured to receive the circuit board(s) 212, as described further below. Thus, except for the region where the circuit board(s) 212 are located, the entire back side 204 of the flat panel display 210 can mate with the front surface 242 of the custom chassis 240.

In some examples, the custom chassis 240 can have one or more openings 226 configured to allow some cables (e.g., similar to flat flex cables 114, etc.) or other electronic components to pass through. In certain examples, the back cover 280 can be affixed to the custom chassis 240 and cover the openings 226. In some examples, one or more braces (similar to 160) can be placed between the flat panel display 210 and the back cover 280 through the openings 226 to transmit the load applied to the flat panel display 210 to the back cover 280 and the custom chassis 240, as described above. In some examples, the back cover 280 and/or the custom chassis 240 can have integrated or built-in bracing member/structure configures to transmit the load.

FIG. 8 depicts the front surface 242 of the custom chassis 240, according to one example. The upper part of the front surface 242 includes the recessed portion 256 configured to receive the circuit board(s) 212. In some examples, the front surface 242 can have a plurality of slightly raised receptors 230 located above the recessed portion 256, e.g., along a top edge 246 of the front surface 242. The receptors 230 can be configured to fit between the corresponding FFCs 214 located on the back side 204 of the flat panel display 210. For example, each of the receptors 230 can have slightly elevated side walls enclosing a middle recess configured to receive the corresponding FFC 214. In some examples, the recessed portion 256 can include a plurality of slightly raised bosses 232 located adjacent (e.g., below) the corresponding receptors 230. The positions of the bosses 232 are configured to face the back side of the circuit board(s) 212 when the custom chassis 240 is mounted to the flat panel display 210.

The front surface 242 of the custom chassis 240 can also include a plurality of slightly recessed grooves 224. The grooves 224 can be interconnected with each other or with gaps therebetween. As shown in FIG. 8, some grooves 224 can be distributed along a bottom edge 248 and two side (left and right) edges 252 of the front surface 242. Additionally, some grooves 224 can also be situated in the middle and/or lower portions of the front surface 242. For example, some of the grooves 224 in the middle portion of the front surface 242 can extend between the left and right edges 252.

The custom chassis 240 can be bonded to the flat panel display 210 by applying one or more adhesive members to selected areas on the front surface 242 of the custom chassis 240. At least some of the adhesive members are deformable under a shear force that is coplanar with the flat panel display 210 such that slightly relative displacement between the flat panel display 210 and the custom chassis 240 under the shear force can be tolerated without damaging the bond therebetween, thereby mitigating the effects of changing temperature on CTEs of different materials, as described above.

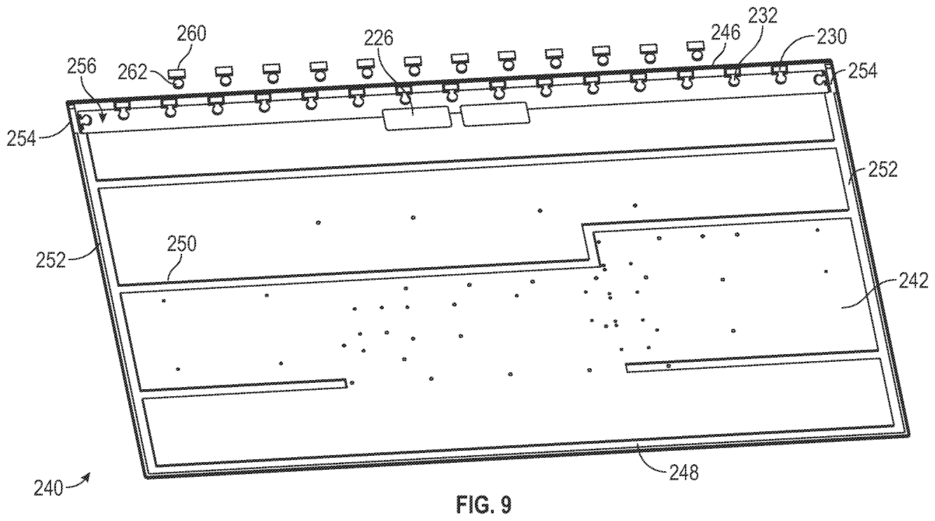

As shown in FIG. 9, adhesive foam tapes 250 can be applied to the grooves 224. The thickness of the foam tapes 250 can be about similar to the depth of the grooves 224 such that the top surface of the foam tapes 250 almost flushes with or is slightly above the front surface 242 adjacent the grooves 224. In one example, during the abuse loading test, the abuse loads can compress the foam tapes 250 located in the grooves 224 to allow the front surface 242 of the custom chassis 240 to contact the back side 204 of the flat panel display 210, thereby providing structural support.

The foam tapes 250 can comprise a silicone foam material (e.g., BISCO® HT-800 provided by Rogers Corporation, etc.) that is deformable under a shear stress between the flat panel display 210 and the custom chassis 240. The foam tapes 250 can have double-sided adhesive surfaces (e.g., with acrylic adhesives) for bonding the custom chassis 240 to the flat panel display 210. For example, a top adhesive surface of the foam tapes 250 can be configured to bond to the front surface 242 of the custom chassis, and a bottom adhesive surface of the foam tapes 250 can be configured to bond to the back side 204 of the flat panel display 210.

As depicted in FIG. 9, corresponding to the locations of the grooves 224, some foam tapes 250 can be applied along the left and right edges 252 of the front surface 242, and some foam tapes 250 can extend between the left and right edges 252 (e.g., forming one or more horizontal strips), including a foam tapes 250 extending along the bottom edge 248. In the depicted example, the foam tapes 250 extend continuously along the left, bottom, and right edges of the front surface 242.

In some examples, another adhesive member can be applied to the top of the custom chassis 240. For example, a plurality of double-sided adhesive strips 260 (e.g., VHBTM tapes provided by 3M Company, etc.) can be applied to the corresponding receptors 230 that are located in isolated areas along the top edge 246 of the front surface 242. For example, for each receptor 230, a bottom surface of an adhesive strip 260 can be adhered to a corresponding receptor 230 (e.g., adhered to the floor of the middle recess enclosed by the elevated side walls), and a top surface of the adhesive strip 260 can be adhered to the front surface 242 of the custom chassis 240. In some examples, the adhesive strips 260 can also be applied to top left and right corners 254 of the front surface 242 (e.g., segments of the left and right edges 252 corresponding to the recessed portion 256).

In some examples, the adhesive strips 260 can have a higher adhesive strength than the adhesive foam tapes 250. Such enhanced adhesive strength can help to prevent delamination between the custom chassis 240 and the flat panel display 210. In some examples, the adhesive strength of the adhesive strips 260 can be at least twice that of the adhesive foam tapes 250. The adhesive strength of the adhesive strips 260 and adhesive foam tapes 250 can be experimentally tested (e.g., via a shear strength test). In one example, the adhesive strength of the adhesive strips 260 must be sufficient to overcome the shear stress applied (due to CTE differences) during a thermal test which varies the temperature within a prespecified range (e.g., between −55° C. and 85° C.). Insufficient adhesive strength may cause delamination of the adhesive strips 260 from the flat panel display 210 and/or the custom chassis 240. In certain examples, the adhesive strips 260 can also be combined with RTV silicone.

In some examples, a plurality of spacers 262 can be attached to the corresponding bosses 232 located in the recessed portion 256. For example, each spacer 262 can have an adhesive bottom surface which is adhered to a corresponding boss 232. The thickness of the spacers 262 is configured to approximately match the distance between the back side of the circuit board(s) 212 and the front surface 242 of the custom chassis 240 such that when mounted, the top surfaces of the spacers 262 can contact and/or interface the back side of the circuit board(s) 212. Relative displacement between the custom chassis 240 and the flat panel display 210 (e.g., during temperature variation) can cause the spacers 262 to slide over the back side of the circuit board(s) 212. The top surfaces of the spacers 262 can have a smooth and/or non-abrasive texture such that the movement of the spacers 262 is smooth and does not damage the circuit boards(s) 212. Additionally, and/or alternatively, a sealant 216 (e.g., RTV silicone or the like) can be used in place of the spacers

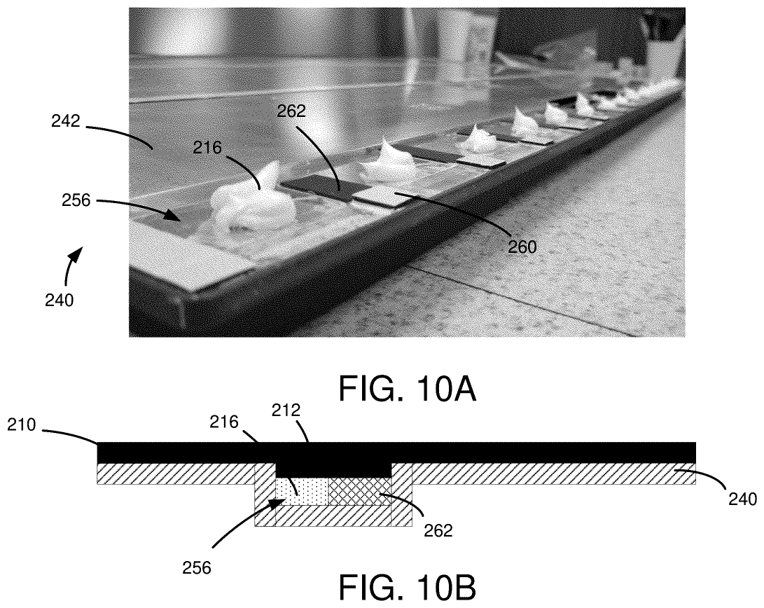

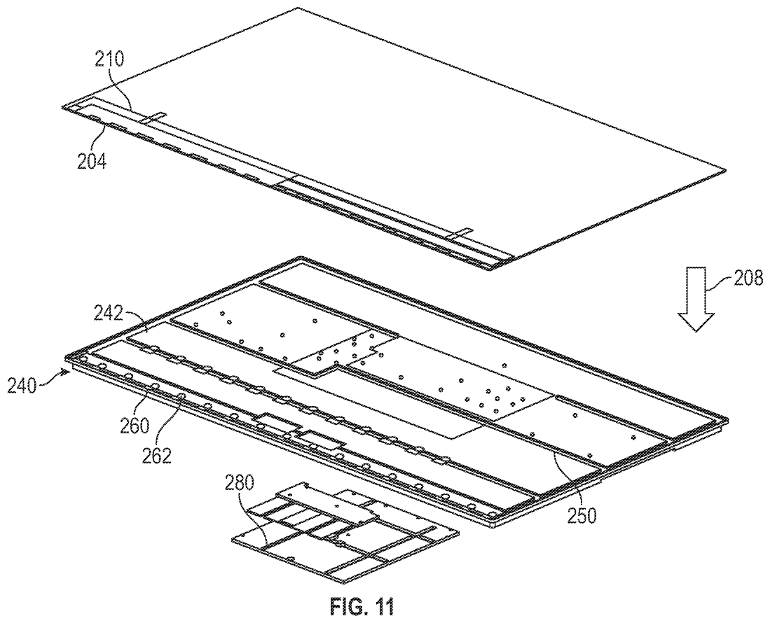

In some examples, a sealant 216 (e.g., RTV silicone or the like) can be applied to the recessed portion 256. As illustrated in FIGS. 10A-10B, the sealant 216 can be applied to the recessed portion 256 at locations adjacent (e.g., on both left and right sides of) the spacers 262. The amount of the applied sealant 216 is configured to fill any voids formed between the back surface of the circuit board(s) 212 and the front surface 242 of the custom chassis 240 when the front surface 242 of the custom chassis 240 is bonded to the back side 204 of the flat panel display 210. In other words, any space or cavity between the back surface of the circuit board(s) 212 and the front surface 242 at the recessed portion 256 that is unoccupied by the spacers 262 can be filled with the sealant 216 (FIG. 10B). Thus, the sealant 216 can serve as a gap filler for uneven surfaces, e.g., the surfaces of the circuit board(s) 212. When fully cured, the sealant 216 can also deform responsive to the relative displacement between the custom chassis 240 and the flat panel display 210 (e.g., during temperature variation). Additionally, spacers 262 and/or the sealants 216 can transmit the load applied to the flat panel display 210 to the custom chassis 240, thereby providing structural support for the upper part of the flat panel display 210 where the circuit board(s) 212 are located.

FIG. 11 illustrates a process for assembling the display assembly 200. First, the custom chassis 240 having the features described above can be prepared. The foam tapes 250 can be applied to the grooves 224 located on the front surface 242 of the custom chassis 240. The plurality of adhesive strips 260 can be adhered to corresponding receptors 230 located on the front surface 242, and the plurality of spacers 262 can be adhered to the corresponding bosses 232 located within the recessed portion 256. Sealants 216 can be applied within the recessed portion 256 besides the spacers 262. The flat panel display 210 can be oriented so that its back side 204 faces and is aligned with the front surface 242 of the custom chassis 240. Then, the flat panel display 210 can be pressed upon the custom chassis 240 so that the foam tapes 250 and/or the adhesive strips 260 can bond them together. In certain examples, weight can be added on top of the flat panel display 210 and/or the back of the custom chassis 240 to facilitate the bonding process. The back cover 280 can then be attached to the back side of the custom chassis 240, e.g., via fasteners or other means.

In certain circumstances, a relatively smaller-sized flat panel display (e.g., less than 42 inches in diagonal measurement) may be mounted to certain locations without using a support chassis. Instead, such smaller-sized flat panel display can be retained by a bezel (e.g., made of aluminum or other materials) which surrounds the top, bottom, and two side edges of the flat panel display. In such case, to prevent the flat panel display to move around behind the bezel (e.g., due to CTE differences at changing temperatures) which can cause vibration and/or fracture of the flat panel display, flexible adhesives (e.g., RTV silicone, etc.) can be applied to edges and/or corners of the bezels so as to create a flexible bonding between the flat panel display and the bezel.

When fully cured, the flexible adhesives can, within a certain limit, allow the flat panel display to contract and/or expand independently to that of the bezel.

### Example Advantages

A number of advantages can be achieved via the technologies described herein.

For example, for flat panel displays having built-in factory chassis which lacks sufficient structural support for the flat panel displays to pass the abuse loading tests, the disclosed technologies can provide improved structural support to the entire back side of the flat panel display, notwithstanding the existence of internal voids enclosed by the factory chassis, and/or electronic components (e.g., cables) unsupported by the factory chassis. Any thin or fragile flat panel displays that need to pass or be designed to support abuse loading tests can benefit from the technologies described herein.

Additionally, for flat panel displays without built-in factory chassis, the disclosed technologies can provide uniform structural support to the flat panel displays using custom chassis. Importantly, the disclosed technologies support flexible bonding between the flat panel displays and the custom chassis so as to tolerate potential displacement between the flat panel displays and the custom chassis caused by CTE differences between different materials as the temperature changes. Any thin or fragile flat panel displays that need to endure temperature variation where there is a CTE difference between materials being bonded can benefit from the technologies described herein.

In view of the many possible embodiments to which the principles of the disclosed technology may be applied, it should be recognized that the illustrated embodiments are only preferred examples of the disclosed technology and should not be taken as limiting the scope of the disclosure. Rather, the scope of the disclosure is defined by the following claims.

What is claimed is:

1. A method for improving structural support for a display apparatus comprising a flat panel display and a circuit board situated at a back side of the flat panel display, the method comprising:
preparing a chassis;
applying a first adhesive member to selective areas on a front surface of the chassis; and
bonding the front surface of the chassis to the back side of the flat panel display using the first adhesive member,
wherein the first adhesive member is deformable under a shear force that is coplanar with the flat panel display.

2. The method of claim 1, wherein the preparing the chassis comprises shaping the front surface of the chassis to mate with the back side of the flat panel display.

3. The method of claim 1, wherein the preparing the chassis comprises forming a recessed portion on the front surface of the chassis, wherein the recessed portion is configured to receive the circuit board of the display apparatus.

4. The method of claim 3, further comprising attaching one or more spacers to the recessed portion, wherein the one or more spacers are configured to contact a back surface of the circuit board when the front surface of the chassis is bonded to the back side of the flat panel display.

5. The method of claim 4, further comprising applying a sealant to the recessed portion at locations adjacent the one or more spacers, wherein the applied sealant is configured to fill any voids formed between the back surface of the circuit board and an inner surface of the recessed portion when the front surface of the chassis is bonded to the back side of the flat panel display.

6. The method of claim 1, wherein the first adhesive member comprises a foam material having a first adhesive surface and a second adhesive surface opposite to the first adhesive surface, wherein the first adhesive surface is configured to bond to the front surface of the chassis and the second adhesive surface is configured to bond to the back side of the flat panel display.

7. The method of claim 1, wherein the applying the first adhesive member to selective areas of the front surface of the chassis comprises applying the first adhesive member along left and right edges of the front surface of the chassis.

8. The method of claim 7, wherein the applying the first adhesive member to selective areas of the front surface of the chassis comprises applying the first adhesive member along one or more horizontal strips extending between the left and right edges of the front surface of the chassis.

9. The method of claim 7, wherein the applying the first adhesive member to selective areas of the front surface of the chassis comprises applying the first adhesive member along a bottom edge of the front surface of the chassis.

10. The method of claim 9, wherein the first adhesive member extends continuously along the left, bottom, and right edges of the front surface of the chassis.

11. The method of claim 1, further comprising applying a second adhesive member along a top edge of the front surface of the chassis, wherein the second adhesive has a higher adhesive strength than the first adhesive member, wherein the second adhesive also bonds the front surface of the chassis to the back side of the flat panel display.

12. The method of claim 11, wherein the second adhesive member is applied in a plurality of isolated areas along the top edge of the front surface of the chassis.

13. An assembly for improving structural support for a display apparatus, wherein the display apparatus comprises a flat panel display and a circuit board situated at a back side of the flat panel display, the assembly comprising:
a chassis having a front surface configured to mate with the back side of the flat panel display; and
a first adhesive member attached to selective areas of the front surface of the chassis,
wherein the first adhesive member is configured to bond the front surface of the chassis to the back side of the flat panel display,
wherein the first adhesive member is deformable under a shear force that is coplanar with the flat panel display.

14. The assembly of claim 13, further comprising one or more spacers attached to a recessed portion located on the front surface of the chassis,
wherein the recessed portion is configured to receive the circuit board of the display apparatus,
wherein when the front surface of the chassis is bonded to the back side of the flat panel display, the one or more spacers are configured to contact a back surface of the circuit board, and any space between the back surface of the circuit board and an inner surface of the recessed portion that is unoccupied by the one or more spacers is filled with a sealant.

15. The assembly of claim 13, wherein the first adhesive member comprises a foam material having a first adhesive surface and a second adhesive surface opposite to the first adhesive surface, wherein the first adhesive surface is configured to bond to the front surface of the chassis and the second adhesive surface is configured to bond to the back side of the flat panel display.

16. The assembly of claim 13, wherein the first adhesive member is attached to left, right, and bottom edges of the front surface of the chassis.

17. The assembly of claim 16, wherein the first adhesive member extends continuously along the left, bottom, and right edges of the front surface of the chassis.

18. The assembly of claim 16, wherein the first adhesive member is attached to a middle portion of the front surface of the chassis so as to form one or more horizontal strips extending between the left and right edges of the front surface of the chassis.

19. The assembly of claim 13, further comprising a second adhesive member attached to a top edge of the front surface of the chassis, wherein the second adhesive has a higher adhesive strength than the first adhesive member, wherein the second adhesive is also configured to bond the front surface of the chassis to the back side of the flat panel display.

20. The assembly of claim 19, wherein the second adhesive member is attached to a plurality of isolated areas along the top edge of the front surface of the chassis.
